(19) United States
(12) Patent Application Publication
(10) Pub. No.: US 2008/0149948 A1
(43) Pub. Date: Jun. 26, 2008

(54) Edge-Emitting Light-Emitting Diode Arrays and Methods of Making and Using the Same

(75) Inventors: Brian T. Mayers, Somerville, MA (US); Jeffrey Carbeck, Belmont, MA (US); Wajeeh Saadi, Cambridge, MA (US); George M. Whitesides, Newton, MA (US)

Correspondence Address: STERNE, KESSLER, GOLDSTEIN & FOX P.L.L.C., 1100 NEW YORK AVENUE, N.W., WASHINGTON, DC, 20005, US

(73) Assignee: Nano Terra Inc., Cambridge, MA (US)

(21) Appl. No.: 11/950,708

(22) Filed: Dec. 5, 2007

Related U.S. Application Data
(60) Provisional application No. 60/872,801, filed on Dec. 5, 2006.

(51) Int. Cl. H01L 33/00

(52) U.S. Cl. 257/89; 438/34; 257/E33.006

(57) ABSTRACT

The present invention is directed to edge-emitting light-emitting diode arrays, a process to prepare the edge-emitting light-emitting diode arrays, and process products prepared by the process.

### CROSS REFERENCE TO RELATED APPLICATIONS

This application claims the benefit of the filing date of U.S. Patent Application No. 60/872,801, filed Dec. 5, 2006, which is incorporated herein by reference in its entirety.

### BACKGROUND OF THE INVENTION

1. Field of the Invention

The present invention is directed to edge-emitting light-emitting diode (“LED”) arrays, processes for making the edge-emitting LED arrays, and process products prepared by the process.

### BACKGROUND

Light emitting diodes (“LEDs”) provide a highly efficient means of light generation. Commercial devices have long employed LEDs because of their long life, energy efficiency, and small size. However, most internal lighting applications continue to use incandescent or fluorescent lighting devices due to the higher brightness and the lower cost of these technologies. What is needed is a high-brightness, white LED that can be prepared by a straight forward, cost efficient process.

The external quantum efficiency, ηₑₓₜ of a LED can be summarized by equation (1):

ηₑₓₜ=γηᵣφη_{oc} (1)

where γ represents the internal quantum efficiency of charge combination within the active region of a device (i.e., formation of an electron-hole pair), ηᵣ represents the quantum efficiency of forming a singlet exciton from the electron-hole pair, φ represents the quantum yield of emission from the singlet exciton, and η_{oc} represents the light emission output coupling efficiency (e.g., the efficiency with which light leaves the device). While the first three terms in equation (1) have values approaching 100% efficiency, the efficiency of output coupling of light, η_{oc}, represents a major hurdle to the commercial development of LEDs.

Only about 2% to about 20% of the internally generated light is emitted from conventional LED devices. There are several reasons for this low output efficiency, the most common being the total internal reflection of light generated within the device due to internal waveguiding. Numerous LED device structures have been provided to improve the outcoupling efficiency (see, e.g., U.S. Pat. Nos. 4,324,944 and 6,980,710; and U.S. Patent Pub. Nos. 2005/0190559 and 2006/0104060, which describe LEDs having various reflective elements). Additionally, the waveguide effect of laminar high-refractive index and low-refractive index materials has also been used to improve the output coupling efficiency (see, e.g., U.S. Pat. Nos. 4,376,946 and 5,907,160; and U.S. Patent Pub. No. 2003/0015770).

Edge-emitting LEDs provide another example of a means of using the waveguide effect to increase output coupling efficiency. U.S. Pat. Nos. 4,590,501 and 6,160,273 describe edge-emitting LED structures wherein a stack of electrodes and active regions effectively act as a waveguide to channel light to the side of a stack where it is emitted. However, the fabrication processes for these edge-emitting LEDs provide their own challenges as to device operation, mass production, and packaging. For example, because the light emerges parallel to the substrate, the LEDs must by diced and packaged using specialized processes.

What is needed is an edge-emitting LED that can be manufactured by a straightforward manufacturing process.

### BRIEF SUMMARY OF THE INVENTION

The present invention provides an edge-emitting LED from which light is emitted at a non-parallel angle to the substrate. Thus, the edge-emitting LEDs of the present invention can be packaged using traditional processes, and provide more efficient outcoupling of light than conventional LEDs. Moreover, the structural features of the edge-emitting LEDs of the present invention permits display devices to be fabricated having a high-density of pixels, as well as the production of lighting devices having red, green, and blue emitting LEDs closely arranged spatially in the lighting device, thus providing a highly efficient source of bright, white light.

The present invention is directed to an edge-emitting LED, comprising: a substrate oriented parallel to a plane; and an active region comprising a p-type portion and an n-type portion having an interfacial boundary therebetween that is not parallel to the plane of the substrate. According to this arrangement, the active region emits light when holes and electrons combine therein, and the incoherent light is emitted from the LED in a direction that is not parallel to the substrate. In some embodiments, light emitted from the edge-emitting LEDs is substantially parallel to the interfacial boundary.

The present invention is directed to an edge-emitting LED comprising:
(a) a substrate having at least one protrusion thereon;
(b) a first conductive layer conformally contacting at least one surface of the protrusion;
(c) an active region conformally contacting the first conductive layer, wherein the active region comprises a p-type portion and an n-type portion having an interfacial boundary therebetween; and
(d) a second conductive layer conformally contacting the active region, wherein the active region emits incoherent light when holes and electrons combine therein, and wherein the incoherent light is emitted from the LED in a direction not parallel to the plane of the substrate.

The present invention is also directed to an edge-emitting LED array comprising:
(a) a substrate including at least one protrusion thereon; and
(b) a plurality of edge-emitting LED elements comprising:
   (i) a first conductive layer contacting at least one surface of the protrusion;
   (ii) an active region contacting the first conductive layer, wherein the active region comprises a p-type portion and an n-type portion having an interfacial boundary therebetween; and
   (iii) a second conductive layer contacting the active region,
wherein the active region emits incoherent light when holes and electrons combine therein, wherein the incoherent light is emitted from the light-emitting diode in a direction not parallel to the plane of the substrate, and wherein at least a portion of the edge-emitting LEDs are absent from a surface of the at least one protrusion, thereby forming an array of discrete edge-emitting LED elements.

The present invention is also directed to a process for manufacturing an edge-emitting LED, the process comprising:
(a) providing a substrate having at least one protrusion thereon;
(b) forming a first conductive layer conformally covering at least one surface of the protrusion;
(c) forming on the first conductive layer an active region comprising a p-type portion and an n-type portion having an interfacial boundary therebetween, wherein the active region conformally covers the first conductive layer;
(d) forming a second conductive layer that conformally covers at least a portion of the active region, and
wherein the active region emits incoherent light when holes and electrons combine therein, and wherein the incoherent light emitted by the active region emits from the light-emitting diode in a direction not parallel to the plane of the substrate.

In some embodiments, the incoherent light is emitted from the LED in a direction substantially parallel to the interfacial boundary.

In some embodiments, the substrate comprises an electrically insulating material.

Protrusions can include three-dimensional shapes such as, but not limited to, a rectilinear polygon, a cylinder, a trigonal pyramid, a square pyramid, a cone, and combinations thereof. Protrusions can also include ridged features having a profile such as, but not limited to, a sinusoidal profile, a parabolic profile, a rectilinear profile, a saw tooth profile, and combinations thereof. In some embodiments, a substrate having at least one protrusion thereon comprises a grating.

In some embodiments, the at least one protrusion has at least one lateral dimension of about 500 nm to about 1 cm.

In some embodiments, the interfacial boundary and the plane of the substrate are oriented relative to each other at an angle of about 10° to 90°. In some embodiments, the incoherent light is emitted from the LED at an angle of about 10° to 90° relative to the plane of the substrate.

In some embodiments the edge-emitting LED further comprises a first electrode and a second electrode, wherein the first electrode contacts the p-type portion of the active region and the second electrode contacts the n-type portion of the active region.

In some embodiments, the active region further comprises an emissive layer, wherein the emissive layer is located at the interfacial boundary between the p-type portion and the n-type portion.

In some embodiments, the edge-emitting LED array further comprises a waveguide layer.

The present invention is also directed to display devices and lighting devices comprising the edge-emitting LEDs of the present invention.

In some embodiments, one or more of the conductive layers comprises a material that reflects a wavelength of light emitted by the active region. In some embodiments, one or more conductive layers comprise a conductor that is transparent to a wavelength of light emitted by the active region.

In some embodiments, the edge-emitting LED further comprises a second active region contacting the second conductive layer, wherein the second active region comprises a p-type portion and an n-type portion having an interfacial boundary therebetween; and a third conductive layer contacting the second active region, wherein the second active region emits incoherent light when holes and electrons combine therein, and wherein the incoherent light emitted by the second active region emits from the LED in a direction not parallel to the plane of the substrate.

In some embodiments, the incoherent light emitted by the first and second active regions has a substantially similar wavelength. In some embodiments, the incoherent light emitted by the first and second active regions has a substantially different wavelength.

In some embodiments, the edge-emitting LED further comprises a third active region contacting the third conductive layer, wherein the third active region comprises a p-type portion and an n-type portion having an interfacial boundary therebetween; and a fourth conductive layer contacting the third active region, wherein the third active region emits incoherent light when holes and electrons combine therein, and wherein the incoherent light is emitted from the third active region in a direction not parallel to the plane of the substrate.

In some embodiments, the incoherent light emitted by the first, second, and third active regions has a substantially similar wavelength. In some embodiments, the incoherent light emitted by the first, second, and third active regions has substantially different wavelength. In some embodiments, the incoherent light emitted by the first, second, and third active regions has wavelengths comprising red, green, and blue colors of the visible spectrum.

In some embodiments of the process of the present invention, forming the first conductive layer comprises selectively depositing a conductive material onto at least one sidewall of the protrusion.

In some embodiments of the process of the present invention, forming the second conductive layer comprises selectively depositing a conductive material onto the active region; and removing any conductive material from a top surface of the protrusion, and any layer deposited thereon.

In some embodiments of the process of the present invention, removing any conductive material from a top surface of the protrusion and any layer deposited thereon is performed by a process chosen from: conformally contacting the conductive material with an adhesive substrate, dry etching the conductive material, wet etching the conductive material, and combinations thereof.

In some embodiments the process of the present invention further comprises forming an emissive layer located at the interfacial boundary between the p-type portion and the n-type portion of the active region.

In some embodiments of the process of the present invention, depositing the active region is performed by a process chosen from: vacuum deposition, chemical vapor deposition, thermal deposition, spin-coating, casting from solution, sputtering, atom layer deposition, and combinations thereof.

In some embodiments, the process of the present invention further comprises forming on the second conductive layer a second active region, wherein the second active region comprises a p-type portion and an n-type portion having an interfacial boundary therebetween; and forming a third conductive layer covering at least a portion of the second active region; wherein the second active region emits incoherent light when holes and electrons combine therein, and wherein the incoherent light emitted by the second active region emits from the LED in a direction not parallel to the plane of the substrate.

In some embodiments, the process of the present invention further comprises forming on the third conductive layer a third active region, wherein the third active region comprises a p-type portion and an n-type portion having an interfacial boundary therebetween; and forming a fourth conductive layer covering at least a portion of the third active region; wherein the third active region emits incoherent light when holes and electrons combine therein, and wherein the incoherent light emitted by the third active region emits from the LED in a direction not parallel to the plane of the substrate.

The present invention is also directed to a product prepared by the process of the present invention. In some embodiments, the product is chosen from: a semiconductor device, a display device, a lighting device, and combinations thereof.

Further embodiments, features, and advantages of the present inventions, as well as the structure and operation of the various embodiments of the present invention, are described in detail below with reference to the accompanying drawings.

### BRIEF DESCRIPTION OF THE DRAWINGS

The accompanying drawings, which are incorporated herein and form a part of the specification, illustrate one or more embodiments of the present invention and, together with the description, further serve to explain the principles of the invention and to enable a person skilled in the pertinent art to make and use the invention.

FIGS. 1A, 1B, 1C, and 1D provide schematic cross-sectional representations of substrates having protrusions thereon suitable for use with the present invention.

FIG. 2 provides a schematic cross-sectional representation of a curved substrate having a protrusion thereon suitable for use with the present invention.

FIGS. 3A and 3B provide schematic cross-sectional representations of substrates having protrusions thereon suitable for use with the present invention.

FIGS. 4A, 4B, and 4C provide schematic cross-sectional representations of edge-emitting LEDs of the present invention.

FIGS. 5A and 5B provide schematic cross-sectional representations of further embodiments of edge-emitting LEDs of the present invention.

FIGS. 6-8 provide schematic representations of processes suitable for making edge-emitting LEDs in accordance with the present invention.

One or more embodiments of the present invention will now be described with reference to the accompanying drawings. In the drawings, like reference numbers can indicate identical or functionally similar elements. Additionally, the left-most digit(s) of a reference number can identify the drawing in which the reference number first appears.

### DETAILED DESCRIPTION OF THE INVENTION

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment”, “an embodiment”, “an example embodiment”, etc., indicate that the embodiment(s) described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

### Substrates for the Edge-Emitting LEDs

The edge-emitting LEDs of the present invention are formed on a substrate. The substrate is not particularly limited by its shape or size, and suitable substrates include planar, curved, circular, wavy, and topographically patterned substrates. While not limited to planar substrates, the substrates of the present invention are capable of being oriented relative to a plane. For flexible substrates, or substrates having a curved topography, the substrates can be oriented such that a tangent to a curve of the substrate is oriented relative to a plane.

Substrates for use with the present invention are not particularly limited by composition. Substrates suitable for use with the present invention include, but are not limited to, metals, alloys, composites, crystalline materials, amorphous materials, conductors, semiconductors, insulators (i.e., an electrically insulating material), optics, glasses, ceramics, zeolites, plastics, films, thin films, laminates, foils, plastics, polymers, minerals, and combinations thereof. Additionally, suitable substrates include both rigid and flexible materials.

In some embodiments, the substrate comprises a semiconductor such as, but not limited to: crystalline silicon, polycrystalline silicon, amorphous silicon, p-doped silicon, n-doped silicon, silicon oxide, silicon germanium, germanium, gallium arsenide, gallium arsenide phosphide, indium tin oxide, and combinations thereof.

In some embodiments, the substrate comprises a glass such as, but not limited to, undoped silica glass (SiO₂), fluorinated silica glass, borosilicate glass, borophosphorosilicate glass, organosilicate glass, porous organosilicate glass, and combinations thereof.

In some embodiments, the substrate comprises a ceramic such as, but not limited to, silicon carbide, hydrogenated silicon carbide, silicon nitride, silicon carbonitride, silicon oxynitride, silicon oxycarbide, and combinations thereof.

In some embodiments, the substrate comprises a flexible material, such as, but not limited to: a plastic, a composite, a laminate, a thin film, a metal foil, and combinations thereof.

In some embodiments, a substrate for use with the present invention comprises a substrate having at least one protrusion thereon. As used herein, a “protrusion” refers to an area of a substrate that is contiguous with, and topographically distinguishable from, an area of a substrate surrounding the protrusion. Additionally, in some embodiments a protrusion can be distinguished from an area of a substrate surrounding the protrusion based upon the composition of the protrusion, or another property of the protrusion that differs from an area of the substrate surrounding the protrusion. In some embodiments, a protrusion can have a three-dimensional shape such as, but not limited to, a rectilinear polygon, a cylinder, a pyramid (e.g., a trigonal pyramid, square pyramid, a pentagonal pyramid, a hexagonal pyramid, etc.), a trapezoid, a cone, and combinations thereof. In some embodiments, a protrusion comprises a ridged feature having a profile such as, but not limited to, a sinusoidal profile, a parabolic profile, a rectilinear profile, a saw tooth profile, and combinations thereof. In those embodiments in which a substrate comprises multiple protrusions, the present invention encompasses all possible spatial arrangements of the protrusions on the substrate including symmetric, asymmetric, ordered, and random spatial arrangements.

All protrusions have at least one lateral dimension. As used herein, a “lateral dimension” refers to a dimension of a protrusion that lies in the plane of a substrate. One or more lateral dimensions of a protrusion define, or can be used to define, the area of a substrate that a protrusion occupies. Typical lateral dimensions of protrusions include, but are not limited to: length, width, radius, diameter, and combinations thereof. A protrusion has at least one lateral and at least one vertical dimension that are typically defined in units of length, such as nanometers (nm), microns (μm), millimeters (mm), etc.

When the surrounding substrate is planar, a lateral dimension of a protrusion is the magnitude of a vector between two points located on opposite sides of the protrusion, wherein the two points are in the plane of the substrate, and wherein the vector is parallel to the plane of the substrate. In some embodiments, two points used to determine a lateral dimension of a symmetric protrusion also lie on a mirror plane of the symmetric protrusion. In some embodiments, a lateral dimension of an asymmetric protrusion can be determined by aligning the vector orthogonally to at least one edge of the protrusion.

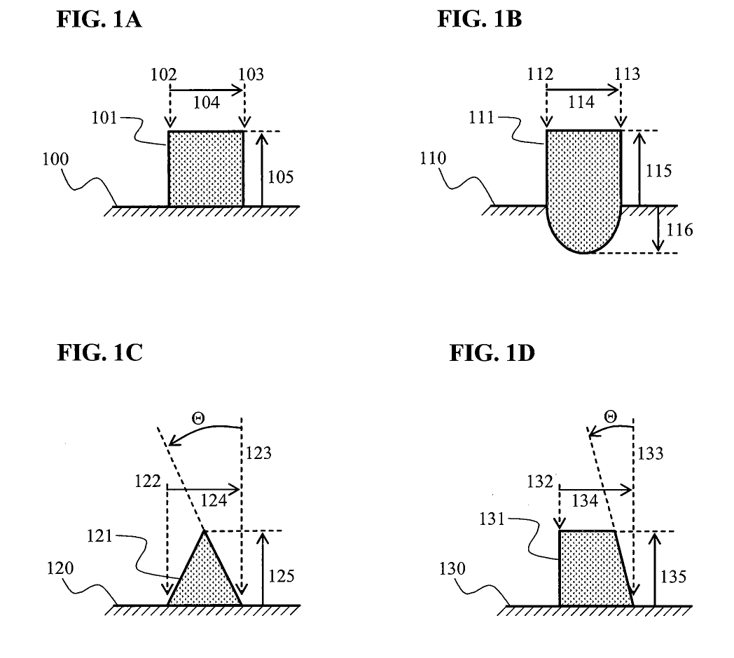

For example, in FIGS. 1A-1D points lying in the plane of the substrate and on opposite sides of the protrusions, 101, 111, 121, and 131, are shown by dashed arrows, 102 and 103; 112 and 113; 122 and 123; and 132 and 133, respectively. The lateral dimension of these protrusions is shown by the magnitude of the vectors 104, 114, 124, and 134, respectively.

A vertical dimension of a protrusion is the magnitude of a vector orthogonal to the substrate between a point in the plane of the substrate and a point at the top-most height of the protrusion. For example, in FIGS. 1A-1D the vertical dimensions of the protrusions are shown by the magnitude of the vectors 105, 115, 125, and 135, respectively. As used herein, a surface of a protrusion refers to any surface of a protrusion including, but not limited to, a sidewall, a top surface, and combinations thereof. For example, in FIGS. 1A-1D protrusions 101, 111, 121, and 131 are shown having sidewalls 106, 116, 126, and 136, respectively. In those embodiments in which the sidewall of a protrusion is orthogonal to a plane oriented parallel to the substrate, the height of the sidewall is equal to the vertical dimension of the protrusion.

While the protrusions illustrated schematically in FIGS. 1A-1D show that the protrusions 101, 111, 121, and 131 have a composition that differs from the surrounding substrate, the present invention encompasses protrusions having both the same or different chemical composition compared to the substrate. For example, a protrusion can be formed by an additive process (e.g., deposition), a subtractive process (e.g., etching), and combinations thereof.

In some embodiments, a protrusion has an “angled” sidewall. As used herein, an “angled sidewall” refers to a sidewall that is not orthogonal to a plane oriented parallel to the substrate. The sidewall angle is equal to the angle formed between a vector orthogonal to the surface that intersects an edge of a protrusion and a vector intersecting the edge of the protrusion at the same point that is parallel to the surface of the sidewall. An orthogonal sidewall has a sidewall angle of 0°. For example, the sidewall angle in FIGS. 1C and 1D of the protrusions 121 and 131 is shown as Θ. In some embodiments, a protrusion on the substrate has a sidewall angle of about 80° to about −50°, about 80° to about −30°, about 80° to about −10°, or about 80° to about 0°.

Not being bound by any particular theory, the sidewall angle of a protrusion can determine the angle at which light is emitted from the edge-emitting LED. For example, an edge-emitting LED of the present invention having a sidewall angle of 20° can emit light at an angle of about 70° relative to a plane oriented parallel to the plane of the substrate. In some embodiments, light is emitted from the edge-emitting LED at an angle of about 10° to 90° relative to a plane oriented parallel to the plane of the substrate.

A substrate is “curved” when the radius of curvature of a substrate is non-zero over a distance on the substrate of 1 mm or more, or over a distance on the substrate of 10 mm or more. For a curved substrate, a lateral dimension is defined as the magnitude of a segment of the circumference of a circle connecting two points on opposite sides of a protrusion, wherein the circle has a radius equal to the radius of curvature of the substrate. A lateral dimension of a curved substrate having multiple or undulating curvature, or waviness, can be determined by summing the magnitude of segments from multiple circles.

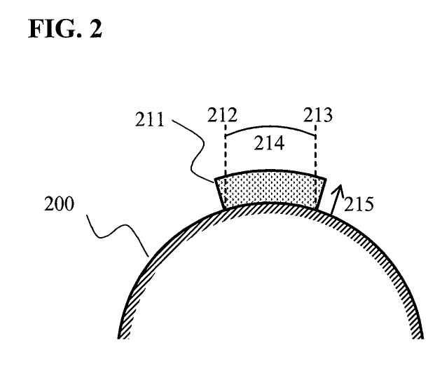

FIG. 2 displays a cross-sectional schematic of a curved substrate, 200, having a protrusion, 211, thereon. A lateral dimension of the protrusion, 211, is equivalent to the length of the line segment, 214, which can connect points 212 and 213. Protrusion 211 has a vertical dimension shown by the magnitude of vector 215.

In some embodiments, a substrate having at least one protrusion thereon comprises a grating. Gratings suitable for use as substrates with the present invention include those generally known in the optical arts, including grating fabricated by methods of contact printing, imprint lithograph, and microcontact molding (see, e.g., U.S. Pat. Nos. 5,512,131; 5,900,160; 6,180,239; 6,719,868; 6,747,285; and 6,776,094, and U.S. Patent Application Pub. Nos. 2004/0225954 and 2005/0133741, which are incorporated herein by reference in their entirety).

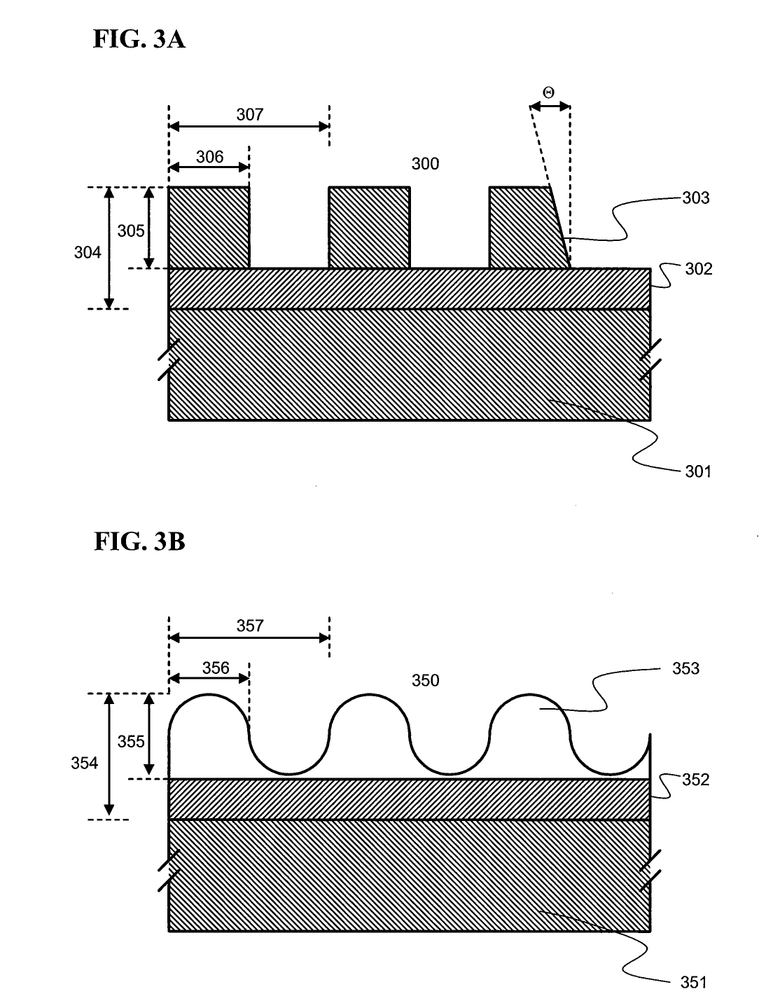

FIGS. 3A and 3B provide schematic cross-sectional representations of gratings, 300 and 350, respectively, suitable for use with the present invention. Referring to FIG. 3A, a grating for use with the present invention comprises a substrate, 301, having an optional top layer, 302, the composition of which can be the same or different, and a grating comprising a series of protrusions, 303, having a height, 305, a width, 306, and a periodicity (i.e., repeat distance), 307. In some embodiments, the repeat distance and/or width of the grating can vary across the distance of the grating. In some embodiments, the sidewalls of the grating are angled, and have a “sidewall angle” or “blaze angle,” Θ, of 0° to about 80°. Gratings for use with the present invention need not have a rectilinear profile, as shown in FIG. 3A, but can have a sinusoidal profile, a parabolic profile, a rectilinear profile, a saw tooth profile, and combinations thereof. For example, FIG. 3B provides a cross-sectional schematic representation of a grating have a sinusoidal profile. The grating, 350, comprises a substrate, 351, having an optional top layer, 352, the composition of which can the same or different, and a grating made up of a series of protrusions, 353, having a sinusoidal shape and a height, 355, width, 356, and repeat distance, 357.

In some embodiments, a substrate for use with the present invention includes at least one protrusion having a lateral dimension of about 50 nm to about 1 cm. In some embodiments, a substrate for use with the present invention includes at least one protrusion having a minimum lateral dimension of about 50 nm, about 100 nm, about 200 nm, about 500 nm, about 1 μm, about 2 μm, about 5 μm, about 10 μm, about 20 μm, about 50 μm, about 100 μm, about 500 μm, about 1 mm, about 2 mm, about 5 mm, or about 1 cm.

In some embodiments, a protrusion has an elevation of about 100 nm to about 1 cm above a plane or the curvature of a surface. In some embodiments, a protrusion has a minimum elevation of about 100 nm, about 200 nm, about 300 nm, about 500 nm, about 1 μm, about 2 μm, about 5 μm, about 10 um, about 20 μm, about 50 μm, about 100 μm, or about 200 μm above the plane or curvature of a surface. In some embodiments, a protrusion has a maximum elevation of about 1 cm, about 5 mm, about 2 mm, about 1 mm, about 500 μm, about 200 μm, about 100 μm, about 50 μm, about 20 μm, about 10 μm, about 5 μm, about 2 μm, about 1 μm, or about 500 nm above the plane of a surface.

The substrates suitable for use with the present invention, and the edge-emitting LEDs fabricated thereon can be structurally and compositionally characterized using analytical methods known to those of ordinary skill in the art of semiconductor device fabrication.

### Edge-Emitting LEDs

The present invention is directed to an edge-emitting LED comprising: a substrate having at least one protrusion thereon; a first conductive layer contacting at least one surface of the protrusion; an active region contacting the first conductive layer, wherein the active region comprises a p-type portion and an n-type portion having an interfacial boundary therebetween; and a second conductive layer contacting the active region, wherein the active region emits incoherent light when holes and electrons combine therein, and wherein light is emitted from the LED in a direction not parallel to the plane of the substrate.

The present invention is also directed to an edge-emitting LED, comprising: a substrate oriented parallel to a plane, and an active region comprising a p-type portion and an n-type portion having an interfacial boundary therebetween that is not parallel to the plane of the substrate, wherein the active region emits incoherent light when holes and electrons combine therein, and wherein the incoherent light is emitted from the LED in a direction substantially parallel to the interfacial boundary.

As used herein, a “light-emitting diode” refers to a solid state device that emits light from a p-n junction. As used herein, an “edge-emitting” LED refers to a solid state device that emits light from a p-n junction in a direction substantially parallel to (i.e., not perpendicular to) an interfacial boundary separating the p-type portion from the n-type portion of the p-n junction.

The edge-emitting LEDs of the present invention are suitable for emitting incoherent light. As used herein, “incoherent” refers to a light whose photons have differing optical properties (e.g., wavelength, phase, and/or direction). The present invention does not comprise LEDs capable of emitting coherent light (i.e., lasers and the like). As used herein, “light” refers to radiation within the ultraviolet (i.e., wavelengths of about 200 nm to about 400 nm), visible (i.e., wavelengths about 400 nm to about 750 nm), and infrared (i.e., wavelengths of about 750 nm to about 2000 nm) regions of the electromagnetic spectrum. Not being bound by any particular theory, the wavelengths emitted by the LEDs of the present invention can be selected by employing materials for the active region and/or emissive region that emit light in the desired regions of the spectrum. In some embodiments, the LEDs of the present invention emit combinations of wavelengths that are suitable for use in white-light emitting device applications. For example, an LED array of the present invention can comprise LEDs that individually emit blue (about 400 nm to about 475 nm), green (about 500 nm to about 540 nm), and red (about 630 nm to about 750 nm) wavelengths of the visible spectrum.

The edge-emitting LEDs of the present invention can emit light from the front plane or back plane of the devices. For example, if a transparent substrate is used, a reflective planarization layer or conformal layer can be deposited onto the devices (i.e., deposited onto the surface of the substrate and the at least one protrusion on which the devices are formed), thereby inducing light emitted by the LEDs to be reflected through the substrate (i.e., out of the “backside” of the device). In some embodiments, the substrate is non-transparent, and edge-emitting LED devices of the present invention formed thereon emit light from the “front” face of the substrate. In some embodiments, one or more transparent or semi-transparent layers can be formed over the edge-emitting LEDs, for example, as protective coatings, filters, and the like.

The edge-emitting LEDs of the present invention comprise an active region. As used herein, an “active region” refers to the region of the LED in which charge transport, charge combination, and light emission occurs. The active region comprises a p-type portion suitable for transporting holes (i.e., conducting positive charge) and an n-type portion suitable for transporting charge (i.e., conducting electrons). Combination of holes and electrons within the active region results in the formation of activated species that emit light. Each of the p-type portion and n-type portion of the active region can comprise one or more layers to enhance and/or optimize charge conduction, charge transfer, charge combination, etc. Thus, p-type and n-type portions comprising individual layers and laminar structures comprising multiple stacked layers are both within the scope of the present invention. Materials suitable for use as materials in the active region (as e.g., p-type portion, n-type portion, and emissive layer) of the edge-emitting LEDs of the present invention include those materials disclosed, for example but not limitation, in U.S. Pat. Nos. 6,048,630; 6,329,085; and 6,358,631, and Light-Emitting Diodes, 2d Ed., Schubert, E. F., Cambridge University Press, NY (2006), which are incorporated herein by reference in their entirety.

In some embodiments, the p-type portion, n-type portion, emissive layer, and combinations thereof comprise an inorganic materials such as, but not limited, to an alloy, crystal, or element. Suitable inorganic materials for use with the present invention include, but are not limited to, those described in High Brightness Light Emitting Diodes, Stringfellow, G. B. and Craford, M. G., Academic Press, San Diego, Calif. (1997), which is incorporated herein by reference in its entirety. In some embodiments, the p-type portion, n-type portion, emissive layer, and combinations thereof comprise an organic material (e.g., an organic polymer, a polyaromatic hydrocarbon, and combinations and derivatives thereof). Suitable organic materials for use with the present invention include, but are not limited to, those described in Organic Light-Emitting Diodes (Optical Engineering), Kalinowski, J., Marcel Dekker, New York, N.Y. (2005), which is incorporated herein by reference in its entirety.

The active region of the edge-emitting LEDs comprises a p-type portion and an n-type portion having at least one interfacial surface therebetween. The interfacial surface has no particular shape or morphology, and can be planar or curved (e.g., concave or convex), and can be smooth, roughened, or have a varying degree of roughness. At least a portion of the interfacial surface is non-planar (i.e., non-conformal) with the surface of the substrate, or for a curved substrate, at least a portion of the interfacial surface is not parallel with a line lying a constant distance above the surface (e.g., a line concentric with the surface).

In some embodiments, the active layer forms a conformal layer on at least a portion of the at least one protrusion. In some embodiments, the active layer can also form a conformal layer on at least a portion of a surface of the substrate. As used herein, a “conformal layer” and “conformally contacting” refer to a layer deposited on a surface of a substrate and/or a surface of a protrusion in a manner such that the thickness of the layer varies by not more than about 50%, not more than about 40%, not more than about 30%, not more than about 25%, not more than about 20%, not more than about 15%, not more than about 10%, or not more than about 5% across the thickness of the layer, and thus the topography of the surface of the layer “conforms” to the three dimensional shape of the underlying surface or surfaces onto which the layer is deposited. The thickness of a conformal active layer can be about 10 nm to about 10 μm. In some embodiments, a conformal active layer can have a minimum thickness of about 10 nm, about 20 nm, about 50 nm, about 100 nm, about 150 nm, about 200 nm, about 250 nm, about 300 nm, about 400 nm, about 500 nm, about 600 nm, about 800 nm, about 1 μm, about 2 μm, about 5 μm, or about 10 μm.

Not being bound by any particular theory, a non-parallel orientation of an interfacial surface within the active layer can facilitate the output coupling of light from the edge-emitting LED devices of the present invention. In some embodiments, the interfacial surface is oriented substantially parallel with a sidewall of a protrusion on which the p-type and n-type portions are formed (e.g., when the layers of the active layer are conformal with the at least one protrusion and/or the surface of the substrate). In some embodiments, the interfacial surface is oriented at an angle of about 10° to 90°, about 20° to 90°, about 45° to 90°, about 60° to 90°, or about 75° to 90° relative to a plane oriented parallel with the substrate. It is also within the scope of the present invention that the LED structures comprise a plurality of interfacial surfaces, each oriented at the same or a different angle relative to a plane oriented parallel to the substrate.

The active region emits incoherent light in a direction substantially parallel to the interfacial boundary when holes and electrons combine therein. As used herein, “substantially parallel” refers to the vector at which light is emitted from the LEDs as forming an angle of about −45° to about 45°, about −30° to about 30°, about −20° to about 20°, or about −15° to about 15°, relative to a plane oriented parallel to the angle of an interfacial boundary.

In some embodiments, the active region emits light in a direction not parallel to the plane of the substrate when holes and electrons combine therein. As used herein, “a direction not parallel to the substrate” refers to a vector formed at the angle at which light is emitted from an LED of the present invention is not parallel to a plane oriented parallel to the plane of the substrate. Thus, light is emitted from the edge of a conductive layer, active region, or waveguide layer of which the LEDs are comprised, and wherein the direction of light emission is out of the plane of the substrate. In some embodiments, a direction not parallel to the substrate refers to an orientation relative to a surface of the substrate of at least about 10°, at least about 15°, at least about 20°, at least about 25°, at least about 30°, at least about 40°, at least about 50°, at least about 60°, or at least about 70° out of the plane of an area of the substrate.

In some embodiments, the active region emits light in a direction substantially parallel to the orientation of the interfacial boundary (e.g., an orientation of about −30° to about +30° relative to surface of the interfacial boundary, or in some embodiments about −20° to about +20° relative to surface of the interfacial boundary, or in some embodiments about −10° to about +10° relative to surface of the interfacial boundary).

The present invention is also directed to an edge-emitting LED array comprising:
(a) a substrate including at least one protrusion thereon; and
(b) a plurality of edge-emitting LED elements comprising:
   (i) a first conductive layer contacting at least one surface of the protrusion;
   (ii) an active region contacting the first conductive layer, wherein the active region comprises a p-type portion and an n-type portion having an interfacial boundary therebetween; and
   (iii) a second conductive layer contacting the active region,
wherein the active region emits incoherent light when holes and electrons combine therein, wherein the incoherent light is emitted from the LED in a direction not parallel to the plane of the substrate, and wherein at least a portion of the edge-emitting LEDs are absent from a surface of the at least one protrusion, thereby forming an array of discrete edge-emitting LED elements.

As used herein, the term “at least a portion of the edge-emitting light-emitting diodes are absent from a surface of the at least one protrusion” refers to at least one of the first conducting layer, the p-type portion of the active layer, the n-type portion of the active layer, the second conductive layer, or combinations thereof being absent from at least one surface of the at least one protrusion. The at least one surface of the at least one protrusion can comprise any surface of the at least one protrusion (e.g., a sidewall of the at least one protrusion, an upper surface of the at least one protrusion, or any combination thereof).

In some embodiments, the active region further comprises a light emissive layer, wherein the light emissive layer is located at the interfacial boundary between a p-type portion and an n-type portion of the active region. Generally, materials suitable for use in an emissive layer of the present invention undergo rapid fluorescence, or undergo phosphorescence with a high quantum efficiency. Materials suitable for use in the emissive layer of the present invention include, but are not limited to, those described in U.S. Pat. Nos. 5,962,971; 6,313,261; 6,967,437; and 7,094,362, which are incorporated herein by reference in their entirety.

Electrodes (an anode and a cathode) are electrically connected or otherwise coupled to the p-type and n-type portions of the active region, respectively. Electrode materials suitable for use with the present invention include metallic or doped polycrystalline silicon, nanocrystalline silicon, conductive oligomers and polymers, and other conductors known to those of skill in the art. Conductive polymers and oligomers suitable for use with the present invention include, but are not limited to, polyacetylene, polythiophenes (e.g., poly(3,4-ethylenedioxythiophene), polystyrenes (e.g., poly(styrenesulfonate), polypyrroles, polyfluorenes, polynaphthalenes, polyphenylenesulfides, polyanilines, polyphenylenevinylenes, and combinations and copolymers thereof. In some embodiments the electrode material comprises a conductive material transparent to a wavelength of light emitted by the active region. Transparent conductive materials suitable for use with the present invention include, but are not limited to, indium tin oxide (“ITO”), metal-doped ITO, carbon nanotubes, zinc oxyfluoride, and combinations thereof. In some embodiments, an electrode (i.e., an anode or cathode) for use with the present invention comprises a metal chosen from: a Group IA metal, a Group IIA metal, a Group IIIB metal, a Group IVB metal, a Group VB metal, a Group VIB metal, Group VIIB metal, a Group VIIIB metal, a Group IB metal, a Group IIB metal, a Group IIIA metal, a Group IVA metal, a Group VA metal, a Group VIA metal, and combinations thereof. In some embodiments, an electrode comprises a material selected from the group that includes, but it not limited to, Al, Ni, Au, Ag, Pd, Pt, Cr, LiF, and combinations thereof. Suitable electrode materials for use with the present invention also include those described in Frontiers of Electrochemistry, the Electrochemistry of Novel Materials, Lipowski, J. and Ross, P. N. Eds., Wiley-VCH Verlag GmbH & Co. KGaA, Weinheim, Germany (1994), which is incorporated herein by reference in its entirety.

In some embodiments, the LEDs of the present invention further comprise a waveguide layer. As used herein, a “waveguide layer” refers to a material adjacent to at least one of an electrode or the active region of an LED, wherein the waveguide layer is transparent to a wavelength of light emitted by the active region, and wherein the waveguide layer has a refractive index greater than that of the layers to which it is adjacent. Not being bound by any particular theory, incoherent light emitted from the active region can be transmitted to the waveguide layer higher, where according to Snell's Law, light incident upon the interface between the waveguide and an adjacent material will undergo total internal reflection within the waveguide material if the light's angle of incidence with a sidewall of the waveguide layer is greater than the critical angle. Internally reflected light within the body of the waveguide can then be emitted from the edge of the waveguide material. The materials and location of the waveguide layer in the present invention are not particularly limited. Materials for use as a waveguide layer include transparent metal oxides, polymers, monomers, sol-gels, and combinations thereof having a refractive index of about 1.6 or greater, about 1.8 or greater, about 2.0 or greater, about 2.1 or greater, or about 2.2 or greater. Materials suitable for use in a waveguide layer include, but are not limited to, ITO, silicon nitride, and other materials having a refractive index of 1.6 or greater. In some embodiments, one of the electrodes, the p-type or n-type portions of the active region, or optional filler functions as a waveguide layer.

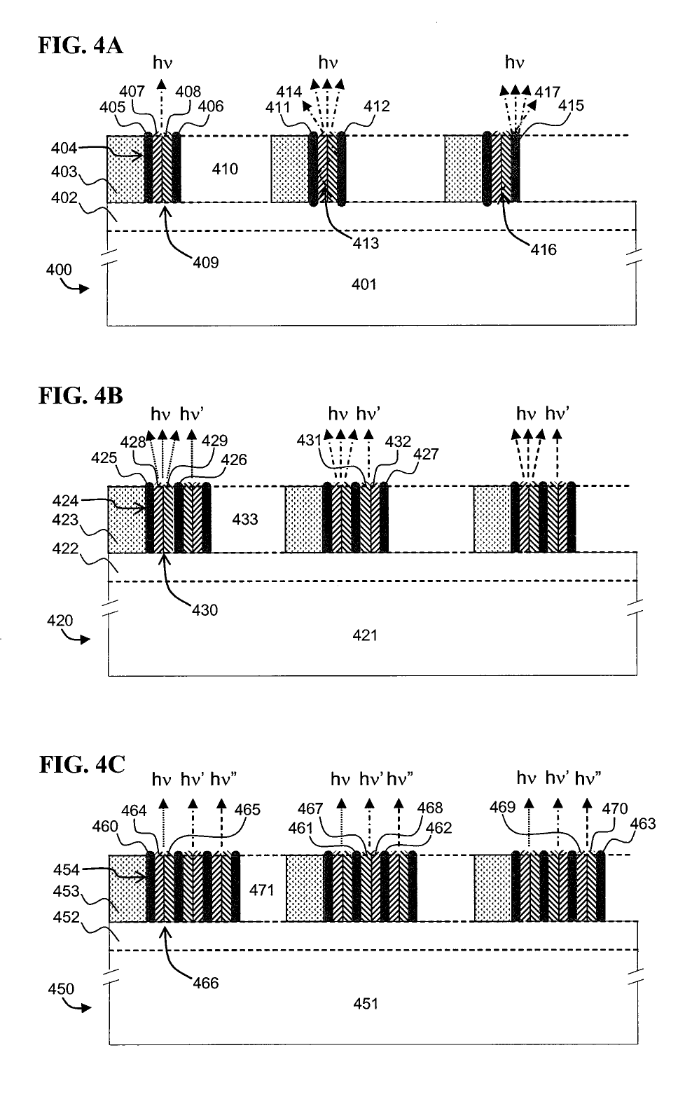

Schematic cross-sectional representations of exemplary edge-emitting LEDs of the present invention are displayed in FIGS. 4A, 4B, and 4C. The edge-emitting LEDs, 400, 420, and 450, have one, two, and three active regions for each protrusion, 403, 423, and 453, respectively. For example, FIG. 4A includes an LED structure, 400, having a substrate, 401 and 402, having a protrusion, 403, thereon. In some embodiments the composition of layers, 401 and 402, is identical. In some embodiments, the composition of the substrate layers, 401 and 402, and the protrusion, 403, are identical. In some embodiments, the substrate layer, 401, is optional. In some embodiments, layer 401 comprises a rigid backing layer, and layer 402 comprises a conformal layer deposited thereon. The protrusion, 403, includes a surface (i.e., a sidewall), 404, onto which a first conductive material, 405, (e.g., an anode) is formed. Between an anode, 405, and a cathode, 406, an active region comprising a p-type portion, 407, and an n-type portion, 408, is formed. The p-type and n-type portions further comprise an interfacial barrier, 409, therebetween. In some embodiments, the edge-emitting LEDs of the present invention further comprise a filler material, 410, that can be deposited to add structural rigidity to the LED devices. Light, hv, is emitted within the active region, 413 and 416. In those embodiments wherein the electrodes, 411 and 412, comprise materials that reflect the wavelengths of light emitted by the active region, light is emitted from the edge-emitting LEDs in a direction, 414, substantially parallel with the orientation of the interfacial surface, 409. In those embodiments wherein at least one electrode, 415, comprises a conductive material that is transparent to a wavelength of light emitted by the active region, the transparent electrode can function as a waveguide, and light emitted by the active region can undergo internal reflection within the waveguide until it is emitted from the edge of the electrode in a direction, 415, substantially parallel with the orientation of the interfacial surface, 409.

FIG. 4B is substantially similar to the edge-emitting LED device described in FIG. 4A, and includes an LED structure, 420, having a substrate, 421 and 422, having a protrusion, 423, thereon that includes a surface (i.e., a sidewall), 424, onto which a first conductive material, 425, (e.g., an anode) is formed. Between an anode, 425, and a cathode, 426, an active region comprising a p-type portion, 428, and an n-type portion, 429, is formed. The p-type portion and n-type portion further comprise an interfacial barrier, 430, therebetween. Opposite the side of the cathode, 426, adjacent to the n-type portion, 429, is a second active region comprising a second n-type portion, 431, and a second p-type portion, 432. Opposite the second p-type portion is a second anode, 427. Light, hv, is similarly emitted from this structure in a direction substantially parallel with the angle of the interfacial surface, 430. In the device illustrated, 420, hv and hv′ can comprise the same or different wavelength(s) of light.

FIG. 4C is substantially similar to the edge-emitting LED device described in FIG. 4B, and includes an LED structure, 450, having a substrate, 451 and 452, having a protrusion, 453, thereon having a surface (i.e., a sidewall), 454, onto which a first conductive material, 460, (e.g., an anode) is formed. Between an anode, 460, and cathode, 461, an active region comprising a p-type portion, 464, and an n-type portion, 465, is formed. The p-type portion and n-type portion further comprise an interfacial barrier, 466, therebetween. Opposite the side of the cathode, 461, adjacent to the n-type portion, 465, is a second active region comprising a second n-type portion, 467, and a second p-type portion, 468. Opposite the second p-type portion, 468, is a second anode, 462, next to which is a third active region comprising a third p-type portion, 469, and a third n-type portion, 470. Opposite the third n-type portion is a second cathode, 463. Light, hv, hv′, and hv″, is emitted from the first, second, and third active regions, respectively, in direction substantially parallel with the interfacial barriers between the p-type and n-type portions, 464 and 465; 466 and 467; and 468 and 469, respectively. The emitted light, hv, hv′, and hv″, respectively, can have the same or different wavelength(s). In some embodiments, the wavelengths of light, hv, hv′, and hv″, are substantially different such as, for example, wavelengths within the red, green, and blue regions of the visible spectrum. Thus, in some embodiments the present invention is suitable for use in lighting devices in which it is desirable to use white light. Additionally, proper selection of emissive materials for use in the edge-emitting LEDs of the present invention permits any combination of desired wavelengths to be emitted from the LEDs including wavelengths of light in the UV, visible, and IR regions of the electromagnetic spectrum.

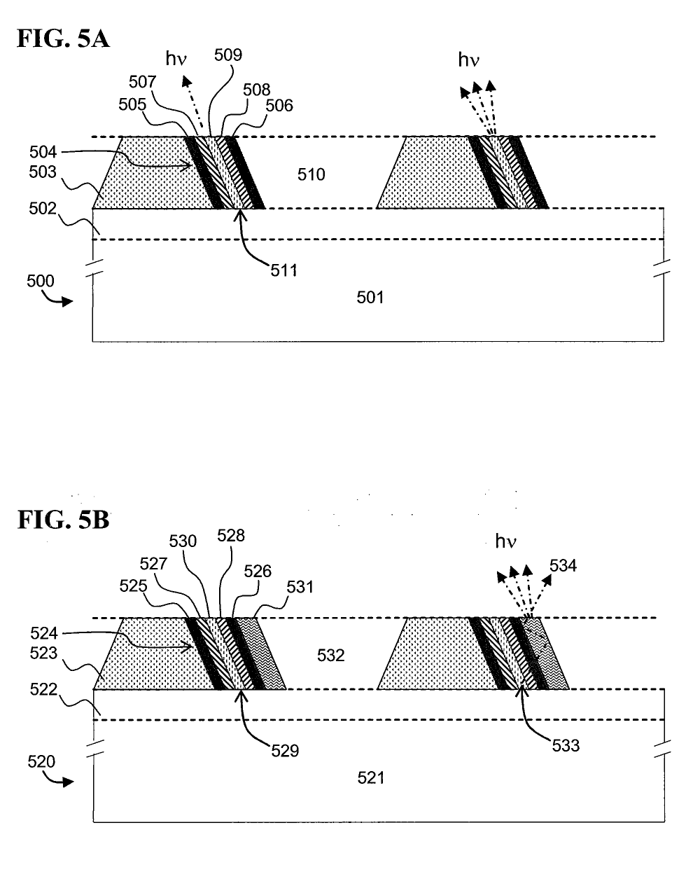

FIG. 5A provides a schematic cross-sectional representation of a further embodiment of an edge-emitting LED device of the present invention. FIG. 5A includes an edge-emitting LED, 500, having a substrate, 501 and 502, having a protrusion thereon, 503, which includes a surface (i.e., a sidewall), 504. In some embodiments the composition of layers, 501 and 502, is identical. In some embodiments, the composition of the substrate layers, 501 and 502, and the protrusion, 503, are identical. In some embodiments, the substrate layer, 501, is optional. A first conductive material, 505, (e.g., an anode) is formed on a portion of the sidewall, 504. Between an anode, 505, and a cathode, 506, an active region comprising a p-type portion, 507, and an n-type portion, 508, is formed. The p-type and n-type portions further comprise an interfacial barrier, 511, therebetween. In this embodiment, a light emissive layer, 509, is present within the interfacial barrier between the p-type and n-type portions. Light, hv, is emitted from the emissive layer in a direction substantially parallel with the orientation of the interfacial barrier. In some embodiments, the edge-emitting LED device further comprises a structural element, 510, that can add rigidity and support to the LED structure.

FIG. 5B provides a schematic cross-sectional representation of another edge-emitting LED device of the present invention. FIG. 5B includes an edge-emitting LED, 520, having a substrate, 521 and 522, having a protrusion thereon, 523, which includes a surface (i.e., a sidewall), 524. In some embodiments the composition of layers, 521 and 522, is identical. In some embodiments, the composition of the substrate layers, 521 and 522, and the protrusion, 523, are identical. In some embodiments, the substrate layer, 521, is optional. A first conductive material, 525, (e.g., an anode) is formed on a portion of the sidewall, 524. Between an anode, 525, and a cathode, 526, which comprises a transparent conductive material, an active region comprising a p-type portion, 527, and an n-type portion, 528, is formed. The p-type and n-type portions further comprise an interfacial barrier, 529, therebetween. In this embodiment, a light emissive layer, 530, is present within the interfacial barrier between the p-type and n-type portions, and a waveguide layer, 531, is present adjacent to the cathode. In some embodiments, the edge-emitting LED device further comprises a structural element, 532, that can add rigidity and support to the LED structure. Light, hv, is emitted within the emissive layer, 533, and can propagate through the emissive layer, 530, the n-type portion of the active region, 528, and transparent cathode, 526, to enter the waveguide material, 531. The emitted light then undergoes internal reflection within the waveguide material until it is emitted in a direction, 534, substantially parallel with the orientation of the interfacial barrier.

### Processes to Prepare the Edge-Emitting LEDs

The present invention is also directed to a process for manufacturing an edge-emitting LED, the process comprising:
(a) providing a substrate having at least one protrusion thereon;
(b) forming a first conductive layer covering at least one surface of the protrusion;
(c) forming on the first conductive layer an active region comprising a p-type portion and an n-type portion having an interfacial boundary therebetween;
(d) forming a second conductive layer that covers at least a portion of the active region, and
wherein the active region emits incoherent light when holes and electrons combine therein, and wherein the light is emitted from the LED in a direction not parallel to the plane of the substrate.

The process of the present invention comprises forming a first conductive layer covering at least one surface of a protrusion. In some embodiments, this forming process is selective such that forming of a conductive layer occurs on a single surface such as a sidewall of a protrusion. Forming processes include, but are not limited to, vapor deposition, plasma-enhanced vapor deposition, thermal deposition, oxidation, reduction, spray-coating, spin-coating, atomization, epitaxial growth, Langmuir deposition, and combinations thereof, and other thin-film deposition and thin-film forming processes known to persons of ordinary skill in the art of thin film deposition.

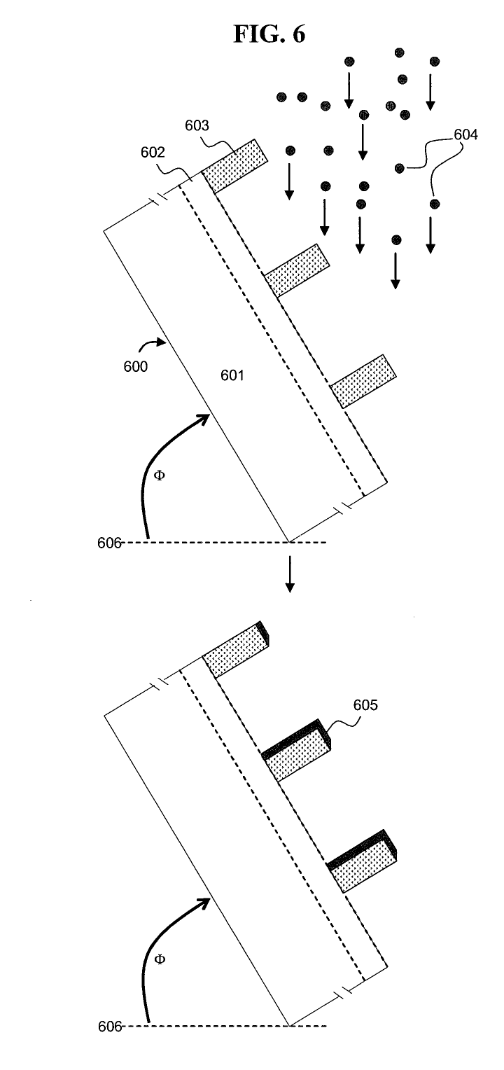

In some embodiments, a substrate can be placed in a vacuum or vapor reactor at an angle, and reactive species can be vapor deposited onto a single surface of a protrusion (e.g., a sidewall). For example, FIG. 6 provides a schematic representation of a deposition process in which a layer, 605, suitable for use with an LED of the present invention, is deposited onto a material, 600, comprising a substrate, 601 and 602, having a protrusion, 603, thereon. The material comprising the substrate and protrusion is oriented at an angle, Φ, relative to the normal plane, 606. A reactive species, 604, deposits onto the top surface and a sidewall of the protrusion, 603, by a vapor deposition process. The angle of orientation, Φ, ensures that deposition occurs only on a first side of the sidewall, and possibly the top surface of the protrusion, depending on the three-dimensional shape of the protrusion. Additional layers can be deposited onto the layer, 605, to form an LED of the present invention. Not being bound by any particular theory, the orientation angle of the substrate, Φ, can determine which surface of a protrusion and/or a substrate a layer is deposited onto.

In some embodiments, the process of the present invention further comprises removing any conductive material from a top surface of the protrusion. Removal of a conductive layer from the top surface of a protrusion can be performed by a contact process (e.g., contacting the top surface of the protrusion with an adhesive film), a dry-etching process, a wet-etching process, and combinations thereof. Not being bound by any particular theory, removal of the conductive layer from the top surface of the protrusion can improve the output efficiency of the edge-emitting LEDs of the present invention by permitting non-transparent conductive materials to be employed in the devices.

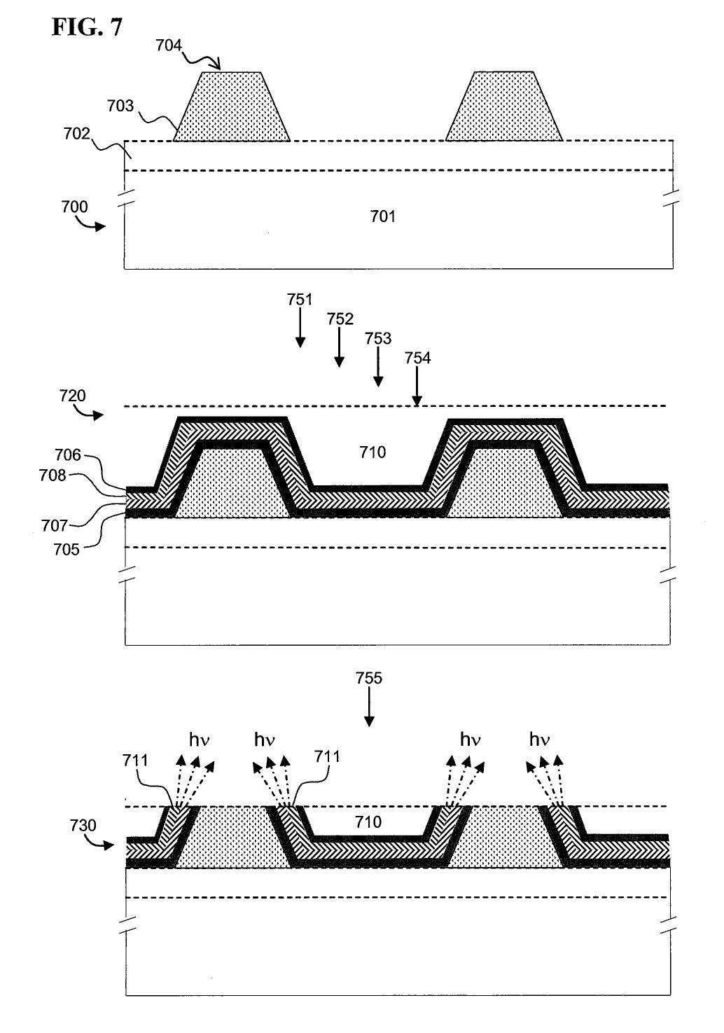

FIG. 7 provides a schematic representation of a process for forming the edge-emitting LEDs of the present invention using conformal deposition methods. A material, 700, comprising a substrate, 701 and 702, having a protrusion, 703, thereon, undergoes consecutive conformal deposition processes, 751, 752, 753, and 754 that conformally deposit a first conductive layer, 705, a p-type portion, 707, an n-type portion, 708, and a second conductive layer, 706, respectively. Optionally, a filler material or structural material, 710, can be deposited onto the conformally deposited layers using an appropriate “gap-fill” deposition process (e.g., plasma-enhanced CVD or spin-coating). The resulting conformal laminar structure, 720, is then subjected to a planarization step, 755, which removes the portions of the conformal layers, 705, 706, 707, and 708 that lie above the plane of the top surface of the protrusion, 704. The resulting LED devices, 730, emit light, hv, in a direction substantially parallel to the interfacial surface within the active region, 711.

Shadow-masks can be employed during the deposition process to selectively deposit the anode, cathode, or any portion of the active region onto different regions of the substrate. For example, selective deposition of the various layers permits facile electrical contact to be made with the anode and cathode, thereby defining an emissive region of the substrate that emits light when a bias is applied to the electrodes.

The surface area of the substrate is not particularly limited can be easily scaled by the proper design of equipment suitable for depositing the electrodes and active region, and can range from about 10 cm² to about 10 m².

In some embodiments, the substrate and/or protrusion can be functionalized, derivatized, textured, or otherwise pre-treated prior to depositing one or more of the conductive and/or active regions of the edge-emitting LED. As used herein, “pre-treating” refers to chemically or physically modifying a substrate prior to applying or deposition. Pre-treating can include, but is not limited to, cleaning, oxidizing, reducing, derivatizing, functionalizing, exposing a surface to a reactive gas, plasma, thermal energy, ultraviolet radiation, and combinations thereof. Not being bound by any particular theory, pre-treating a substrate can increase or decrease an adhesive interaction between two layers, or increase conductivity between layers.

In some embodiments, after deposition of one or more layers, the substrate can be post-treated. Post-treatment can sinter, cross-link, or cure a layer of the LED, as well as, improve conductivity, inter-layer adhesion, density, and combinations thereof.

In some embodiments, one or more of the layers is deposited in a conformal manner. As used herein, “conformal” refers to a layer or coating that is of substantially uniform thickness regardless of the geometry of underlying features. Thus, conformal coating of protrusions of various size and shape can result in edge-emitting LEDs having substantially similar sizes and shapes, and the size of the resulting edge-emitting LED devices can be controlled by selecting the dimensions of a protrusion on a substrate (e.g., the spacing and dimensions of a grating). Conformal deposition methods include, but are not limited to, chemical vapor deposition, spin-coating, casting from solution, dip-coating, atomic layer deposition, self-assembly, and combinations thereof.

In some embodiments, the process of the present invention further comprises depositing a transparent protective layer onto the outward-facing surface of the edge-emitting LEDs.

The LEDs of the present invention are suitable for use in lighting display devices, as well as any electronic devices in which a light source is needed. For example, in some embodiments, LEDs of the present invention can function as a light-emitting element in scientific apparatus (e.g., analytical devices, microfluidic devices, and the like). The LEDs of the present invention can be deposited in combination with (e.g., adjacent to, on top of, or beneath) integrated circuit device elements. In some embodiments, an integrated circuit device (e.g., a transistor) can function as a control element for an LED of the present invention.

### EXAMPLES

### Example 1

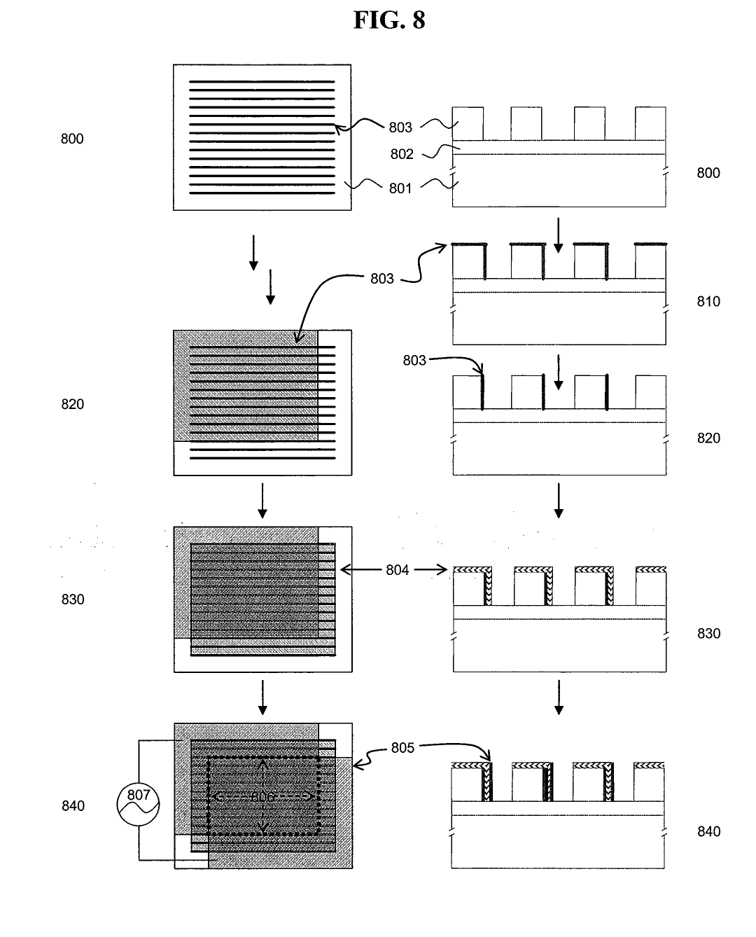

An edge-emitting LED of the present invention will be prepared by a process outlined by the schematic representation in FIG. 8. A substrate, 801 and 802, having a grating, 803, thereon, will be placed in a vacuum reactor. An anode (e.g., Aluminum), followed by a thin (˜100 nm) layer of nickel will be selectively deposited onto one sidewall of the grating, 803, by tilting the substrate during deposition, and selectively deposited onto a selected portion of the substrate through the use of a shadow-mask. Any metal deposited on the top surface of the grating will be removed by contacting the top surface of the grating with an adhesive surface to produce a grating having a metal electrode deposited on only one side of the grating, 820. The active regions, 804, will then be vacuum-deposited over the entire grating. This will be followed by deposition of a cathode (e.g., LiF followed by Al), which will be conducted by again tilting the grating, and using a shadow-mask to deposit cathode over an area of the substrate and grating, 805, offset from area onto which the anode will be deposited. Any metal deposited on the top surface of the grating can again be removed by contacting the top surface of the grating with an adhesive surface, for example. Connecting the anode and cathode to a grounded power source, 807, will result in an edge-emitting LED device. The final edge-emitting LED device will have an emissive surface area, 806, defined by the region on the substrate where the anode and cathode depositions overlap one another.

### Conclusion

These examples illustrate possible embodiments of the present invention. While various embodiments of the present invention have been described above, it should be understood that they have been presented by way of example only, and not limitation. It will be apparent to persons skilled in the relevant art that various changes in form and detail can be made therein without departing from the spirit and scope of the invention.

Thus, the breadth and scope of the present invention should not be limited by any of the above-described exemplary embodiments, but should be defined only in accordance with the following claims and their equivalents.

It is to be appreciated that the Detailed Description section, and not the Summary and Abstract sections, is intended to be used to interpret the claims. The Summary and Abstract sections can set forth one or more, but not all exemplary embodiments of the present invention as contemplated by the inventor(s), and thus, are not intended to limit the present invention and the appended claims in any way.

All documents cited herein, including journal articles or abstracts, published or corresponding U.S. or foreign patent applications, issued or foreign patents, or any other documents, are each entirely incorporated by reference herein, including all data, tables, figures, and text presented in the cited documents.

What is claimed is:

1. An edge-emitting light-emitting diode comprising:
(a) a substrate including at least one protrusion thereon;
(b) a first conductive layer conformally contacting at least one surface of the protrusion;
(c) an active region conformally contacting the first conductive layer, wherein the active region comprises a p-type portion and an n-type portion having an interfacial boundary therebetween; and
(d) a second conductive layer conformally contacting the active region, wherein the active region emits incoherent light when holes and electrons combine therein, and wherein the incoherent light is emitted from the light-emitting diode in a direction not parallel to the plane of the substrate.

2. The edge-emitting light-emitting diode of claim 1, wherein the at least one protrusion is a three-dimensional shape chosen from: a rectilinear polygon, a cylinder, a trigonal pyramid, a square pyramid, a cone, a ridged feature having a sinusoidal profile, a ridged feature having a parabolic profile, a ridged feature having a rectilinear profile, a ridged feature having a saw tooth profile, and combinations thereof.

3. The edge-emitting light-emitting diode of claim 2, wherein the substrate having at least one protrusion thereon comprises a grating.

4. The edge-emitting light-emitting diode of claim 1, wherein the at least one protrusion has at least one lateral dimension of about 500 nm to about 1 mm.

5. The edge-emitting light-emitting diode of claim 1, further comprising:
(e) a second active region contacting the second conductive layer, wherein the second active region comprises a p-type portion and an n-type portion having an interfacial boundary therebetween; and
(f) a third conductive layer contacting the second active region, wherein the second active region emits incoherent light when holes and electrons combine therein, and wherein the incoherent light emitted by the second active region emits from the light-emitting diode in a direction not parallel to the plane of the substrate.

6. The edge-emitting light-emitting diode of claim 5, wherein the incoherent light emitted by the first and second active regions has a substantially similar wavelength.

7. The edge-emitting light-emitting diode of claim 5, wherein the incoherent light emitted by the first and second active regions has a substantially different wavelength.

8. The edge-emitting light-emitting diode of claim 5, further comprising:
(g) a third active region contacting the third conductive layer, wherein the third active region comprises a p-type portion and an n-type portion having an interfacial boundary therebetween; and
(h) a fourth conductive layer contacting the third active region, wherein the third active region emits incoherent light when holes and electrons combine therein, and wherein the incoherent light is emitted from the third active region in a direction not parallel to the plane of the substrate.

9. The edge-emitting light-emitting diode of claim 8, wherein the incoherent light emitted by the first, second, and third active regions has a substantially similar wavelength.

10. The edge-emitting light-emitting diode of claim 8, wherein the incoherent light emitted by the first, second, and third active regions has substantially different wavelength.

11. The edge-emitting light-emitting diode of claim 10, wherein the incoherent light emitted by the first, second, and third active regions comprises wavelengths from the red, green, and blue colors of the spectrum.

12. A display device comprising the edge-emitting light-emitting diode of claim 1.

13. A lighting device comprising the edge-emitting light-emitting diode of claim 1.

14. An edge-emitting light-emitting diode array comprising:
(a) a substrate including at least one protrusion thereon; and
(b) a plurality of edge-emitting light-emitting diode elements comprising:
(i) a first conductive layer contacting at least one surface of the protrusion;
(ii) an active region contacting the first conductive layer, wherein the active region comprises a p-type portion and an n-type portion having an interfacial boundary therebetween; and
(iii) a second conductive layer contacting the active region, wherein the active region emits incoherent light when holes and electrons combine therein, wherein the incoherent light is emitted from the light-emitting diode in a direction not parallel to the plane of the substrate, and wherein at least a portion of the edge-emitting light-emitting diodes are absent from a surface of the at least one protrusion, thereby forming an array of discrete edge-emitting light-emitting diode elements.

15. A process for manufacturing an edge-emitting light-emitting diode, the process comprising:
(a) providing a substrate having at least one protrusion thereon;
(b) forming a first conductive layer conformally covering at least one surface of the protrusion;
(c) forming on the first conductive layer an active region comprising a p-type portion and an n-type portion having an interfacial boundary therebetween, wherein the active region conformally covers the first conductive layer;
(d) forming a second conductive layer that conformally covers at least a portion of the active region, and
wherein the active region emits incoherent light when holes and electrons combine therein, and wherein the incoherent light emitted by the active region emits from the light-emitting diode in a direction not parallel to the plane of the substrate.

16. The process of claim 15, wherein forming the first conductive layer comprises:
(i) selectively depositing a conductive material onto at least one surface of the protrusion.

17. The process of claim 15, wherein forming the second conductive layer comprises:
(i) selectively depositing a conductive material onto the active region; and
(ii) removing any conductive material from a top surface of the protrusion, and any layer deposited thereon.

18. The process of claim 15, further comprising: forming an emissive layer located at the interfacial boundary between the p-type portion and the n-type portion of the active region.

19. The process of claim 15, further comprising:
(e) forming on the second conductive layer a second active region, wherein the second active region comprises a p-type portion and an n-type portion having an interfacial boundary therebetween; and
(f) forming a third conductive layer covering at least a portion of the second active region;
wherein the second active region emits incoherent light when holes and electrons combine therein, and wherein the incoherent light emitted by the second active region emits from the light-emitting diode in a direction not parallel to the plane of the substrate.

20. The process of claim 15, further comprising:
(g) forming on the third conductive layer a third active region, wherein the third active region comprises a p-type portion and an n-type portion having an interfacial boundary therebetween; and
(h) forming a fourth conductive layer covering at least a portion of the third active region;
wherein the third active region emits incoherent light when holes and electrons combine therein, and wherein the incoherent light emitted by the third active region emits from the light-emitting diode in a direction not parallel to the plane of the substrate.

21. A product prepared by the process of claim 15.

22. The product of claim 21, wherein the product is chosen from: a semiconductor device, a display device, a lighting device, and combinations thereof.
